(19) United States
(12) Patent Application Publication
(10) Pub. No.: US 2026/0275100 A1
(43) Pub. Date: Sep. 17, 2026

(54) RESIN COMPOSITION, PREPREG, FILM WITH RESIN, METAL FOIL WITH RESIN, METAL-CLAD LAMINATE, AND WIRING BOARD

(71) Applicant: PANASONIC INTELLECTUAL PROPERTY MANAGEMENT CO., LTD., Osaka (JP)

(72) Inventors: Hirosuke SAITO, Osaka (JP); Kenta KUBO, Ibaraki (JP); Rihoko WATANABE, Osaka (JP)

(73) Assignee: PANASONIC INTELLECTUAL PROPERTY MANAGEMENT CO., LTD., Osaka (JP)

(21) Appl. No.: 19/469,103

(22) PCT Filed: Feb. 28, 2024
(86) PCT No.: PCT/JP2024/007426

§ 371 Date: Sep. 25, 2025

(30) Foreign Application Priority Data
Mar. 30, 2023 (JP) 2023-056557

(51) Int. Cl. C08L 51/08; B32B 5/02; B32B 15/08; C08J 5/24; H05K 1/03

(52) U.S. Cl. CPC C08L 51/08; B32B 5/02; B32B 15/08; C08J 5/244; H05K 1/0366; B32B 2457/08; C08J 2351/08; C08J 2453/02

(57) ABSTRACT

One aspect of the present invention is a resin composition containing a maleimide compound (A) having an indane structure represented by the following Formula (1) in a molecule, a benzoxazine compound (B) having an allyl group in a molecule, and a styrenic polymer (C) that is solid at 25° C.

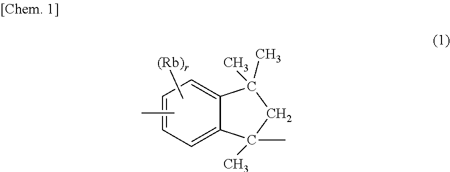

In Formula (1), Rb's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group, and r represents 0 to 3.

### TECHNICAL FIELD

The present invention relates to a resin composition, a prepreg, a film with resin, a metal foil with resin, a metal-clad laminate, and a wiring board.

### BACKGROUND ART

As the information processing quantity by various electronic devices increases, mounting technologies such as high integration of semiconductor devices to be mounted, densification of wiring, and multilayering are progressing. In addition, wiring boards used in various electronic devices are required to be, for example, high-frequency compatible wiring boards such as a millimeter-wave radar board for in-vehicle use. Substrate materials for forming insulating layers of wiring boards used in various electronic devices are required to have a low relative dielectric constant and a low dielectric loss tangent in order to increase the signal transmission speed and to decrease the signal transmission loss. Examples of such a substrate material having a low relative dielectric constant and low dielectric loss tangent include the resin compositions described in Patent Literatures 1 and 2.

Patent Literature 1 describes a resin composition containing a maleimide compound, an allyl group-containing benzoxazine compound, and a high molecular weight component. Patent Literature 1 discloses that it is possible to provide a resin composition, which can afford a cured product having a small dielectric loss tangent value, excellent adhesion to a conductive material after an environmental resistance test, and improved brittleness.

Patent Literature 2 describes a resin composition containing a maleimide compound having an indane structure in the molecule, and a styrenic polymer being solid at 25° C. Patent Literature 2 describes that a resin composition that affords a cured product, which exhibits excellent low dielectric properties and adhesion to a metal foil, has a high glass transition temperature, and sufficiently suppressed increases in relative dielectric constant and dielectric loss tangent due to temperature rise can be provided.

Metal-clad laminates and metal foils with resin used in the manufacture of wiring boards and the like include not only an insulating layer but also a metal foil on the insulating layer. Wiring boards also include not only an insulating layer but also wiring on the insulating layer. Examples of the wiring include wiring derived from a metal foil equipped in the metal-clad laminate or the like.

In recent years, particularly small portable devices such as mobile communication terminals and notebook PCs have been rapidly becoming multi-functional, high performance, slim and compact. Along with this, in wiring boards used in these products as well, there is a demand for miniaturization of conductor wiring, multilayering of conductor wiring layers, thinning, and improvement in performance such as mechanical properties. In particular, as thinning of wiring boards proceeds, problems arise that warpage of semiconductor packages in which semiconductor chips are mounted on wiring boards occurs and mounting failures are likely to occur. In order to suppress warpage of semiconductor packages in which semiconductor chips are mounted on wiring boards, the insulating layers are required to have a low coefficient of thermal expansion (thermal expansion coefficient). Hence, substrate materials for forming insulating layers of wiring boards are required to afford cured products having a low coefficient of thermal expansion.

In the manufacturing of the wiring boards, for example, when conductor wiring layers are multilayered, in order to connect the conductor wiring layers, insulating layers may be drilled with a drill such as a mechanical drill and a laser such as a carbon dioxide laser, and then subjected to desmearing for cleaning the hole formed by the drilling, and then subjected to electrolytic plating such as electroless plating and electrolytic copper plating. It is required that the conductor wiring formed by performing such electroless plating and electrolytic plating is hardly peeled off from the insulating layers. Hence, substrate materials for forming insulating layers of wiring boards are required to afford cured products having high plating adhesion.

Hence, substrate materials for forming insulating layers of wiring boards are required to afford cured products having a low coefficient of thermal expansion and high plating adhesion.

### CITATION LIST

### Patent Literatures

Patent Literature 1: JP 2020-158705 A
Patent Literature 2: WO 2022/054864 A

### SUMMARY OF INVENTION

The present invention has been made in view of such circumstances, and the purpose is to provide a resin composition, which affords a cured product having a low coefficient of thermal expansion and high plating adhesion. Another object of the present invention is to provide a prepreg, a film with resin, a metal foil with resin, a metal-clad laminate, and a wiring board, which are obtained using the resin composition.

One aspect of the present invention is a resin composition containing a maleimide compound (A) having an indane structure represented by the following Formula (1) in a molecule, a benzoxazine compound (B) having an allyl group in a molecule, and a styrenic polymer (C) that is solid at 25° C.

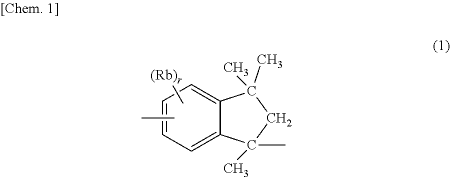

In Formula (1), Rb's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group, and r represents 0 to 3.

The object described above and other objects, features and advantages of the present invention will become apparent from the following detailed description and accompanying drawings.

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

FIG. 4 is a schematic sectional view illustrating an example of a metal foil with resin according to an embodiment of the present invention.

FIG. 5 is a schematic sectional view illustrating an example of a film with resin according to an embodiment of the present invention.

### DESCRIPTION OF EMBODIMENTS

The present inventors have found out that the objects are achieved by the present invention described below as a result of extensive studies.

Hereinafter, embodiments according to the present invention will be described, but the present invention is not limited thereto.

### [Resin Composition]

A resin composition according to an embodiment of the present invention is a resin composition containing a maleimide compound (A) having an indane structure represented by the following Formula (1) in the molecule, a benzoxazine compound (B) having an allyl group in the molecule, and a styrenic polymer (C) that is solid at 25° C. By curing the resin composition, a cured product having a low coefficient of thermal expansion and high plating adhesion is obtained.

### (Maleimide Compound (A))

The maleimide compound (A) is not particularly limited as long as it is a maleimide compound having an indane structure represented by Formula (1) in the molecule. The maleimide compound (A) has not only the indane structure but also a maleimide group in the molecule. Also, specific examples of the maleimide compound (A) include a maleimide compound (A1) having a structure represented by the following Formula (2) in the molecule.

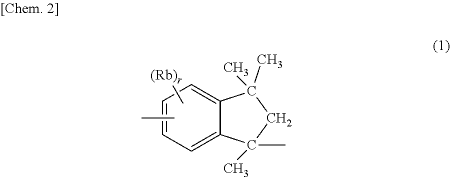

In Formula (1), Rb's are independent of each other. In other words, Rb's may be the same group as or different groups from each other, and for example, when r is 2 or 3, two or three Rb's bonded to the same benzene ring may be the same group as or different groups from each other. Rb represents an alkyl group having 1 to 10 carbon atoms, an alkyloxy group (alkoxy group) having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a nitro group, a halogen atom, a hydroxyl group, or a mercapto group (thiol group). r represents 0 to 3.

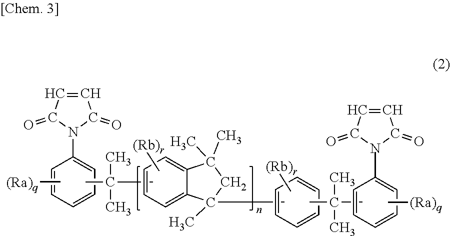

In Formula (2), Ra's are independent of each other. In other words, Ra's may be the same group as or different groups from each other, and for example, when q is 2 to 4, two to four Ra's bonded to the same benzene ring may be the same group as or different groups from each other. Ra represents an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group. Rb is the same as Rb in Formula (1), and Rb's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group. q represents 0 to 4. r represents 0 to 3. n represents 0.95 to 10.

r is the average value of the degree of substitution of Rb, it is more preferable as r is smaller, and specifically, r is preferably 0. In other words, in the benzene ring to which Rb may be bonded, it is preferable that a hydrogen atom is bonded to the position to which Rb may be bonded. It is easy to synthesize the maleimide compound (A) having such r. It is considered that this is because steric hindrance is diminished and the electron density in the aromatic ring increases. When r is 1 to 3, Rb is preferably at least one selected from the group consisting of an alkyl group having 1 to 4 carbon atoms, a cycloalkyl group having 3 to 6 carbon atoms, and an aryl group having 6 to 10 carbon atoms among the above. Ra is preferably at least one selected from the group consisting of an alkyl group having 1 to 4 carbon atoms, a cycloalkyl group having 3 to 6 carbon atoms, and an aryl group having 6 to 10 carbon atoms among the above. As Ra and Rb are an alkyl group having 1 to 4 carbon atoms, a cycloalkyl group having 3 to 6 carbon atoms, or an aryl group having 6 to 10 carbon atoms, it is easy to dissolve the maleimide compound (A) in a solvent as well as a decrease in reactivity of the maleimide group can be suppressed and a suitable cured product is obtained. It is considered that this is due to a decrease in planarity in the vicinity of the maleimide group, a decrease in crystallinity, and the like.

Specific examples of the groups represented by Ra and Rb include the following groups.

The alkyl group having 1 to 10 carbon atoms is not particularly limited, and examples thereof include a methyl group, an ethyl group, a propyl group, a hexyl group and a decyl group.

The alkyloxy group having 1 to 10 carbon atoms is not particularly limited, and examples thereof include a methyloxy group, an ethyloxy group, a propyloxy group, a hexyloxy group and a decyloxy group.

The alkylthio group having 1 to 10 carbon atoms is not particularly limited, and examples thereof include a methylthio group, an ethylthio group, a propylthio group, a hexylthio group and a decylthio group.

The aryl group having 6 to 10 carbon atoms is not particularly limited, and examples thereof include a phenyl group and a naphthyl group.

The aryloxy group having 6 to 10 carbon atoms is not particularly limited, and examples thereof include a phenyloxy group and a naphthyloxy group.

The arylthio group having 6 to 10 carbon atoms is not particularly limited, and examples thereof include a phenylthio group and a naphthylthio group.

The cycloalkyl group having 3 to 10 carbon atoms is not particularly limited, and examples thereof include a cyclopropyl group, a cyclobutyl group, a cyclohexyl group, and a cyclooctyl group.

Examples of the halogen atom include a fluorine atom, a chlorine atom, a bromine atom, and an iodine atom.

q is the average value of the degree of substitution of Ra, and is preferably 2 to 3, more preferably 2. It is easy to synthesize the maleimide compound (A) having such q. It is considered that this is because steric hindrance is diminished and the electron density in the aromatic ring increases particularly when q is 2.

n is the average value of the number of repetitions, and is 0.95 to 10 as described above, preferably 0.98 to 8, more preferably 1 to 7, still more preferably 1.1 to 6. The content of the maleimide compound, which is a maleimide compound represented by Formula (1) and a maleimide compound (A1) represented by Formula (2) and in which n that is the average number of repetitions (degree of polymerization) is 0, is preferably 32% by mass or less with respect to the total amount of the maleimide compound (A).

The molecular weight distribution (Mw/Mn) of the maleimide compound (A) acquired by GPC measurement is preferably 1 to 4, more preferably 1.1 to 3.8, still more preferably 1.2 to 3.6, particularly preferably 1.3 to 3.4. The molecular weight distribution is acquired by gel permeation chromatography (GPC) measurement.

The maleimide compound (A) may have not only the indane structure represented by Formula (1) in the molecule, but also an arylene structure bonded in the meta-orientation in the molecule. That is, examples of the maleimide compound (A) include a maleimide compound having the indane structure and the arylene structure in the molecule. Examples of the arylene structure bonded in the meta-orientation include an arylene structure (an arylene structure in which a structure containing a maleimide group is substituted at the meta position) in which a structure containing a maleimide group (that is, other than Rb) is bonded to the meta position. The arylene structure bonded in the meta-orientation is an arylene group bonded in the meta-orientation, such as a group represented by the following Formula (6). Examples of the arylene structure bonded in the meta-orientation include m-arylene groups such as a m-phenylene group and a m-naphthylene group, and more specific examples thereof include a group represented by the following Formula (6).

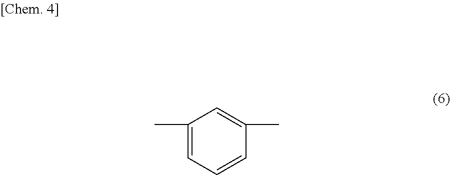

Specific examples of the maleimide compound (A) include maleimide compounds represented by Formulas (7) to (9). These maleimide compounds (A) further have an arylene group bonded in the meta-orientation, such as a group represented by the following Formula (6), in the molecule.

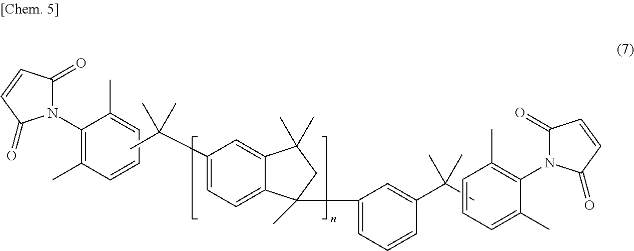

In Formula (7), n represents 0.95 to 10.

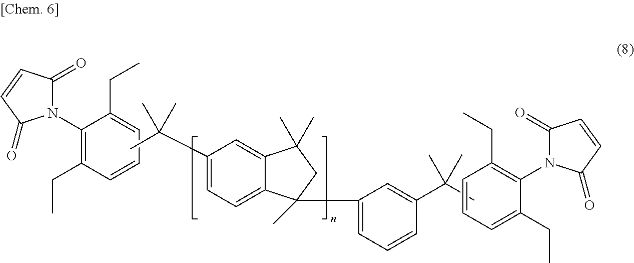

In Formula 8 n represents 0.95 to 10.

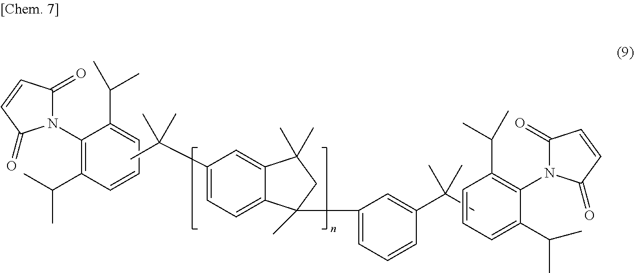

In Formula (9), n represents 0.95 to 10.

The method for producing the maleimide compound (A) is not particularly limited as long as the maleimide compound (A) can be produced. Specifically, the maleimide compound (A) is obtained by a so-called maleimidation reaction in which an amine compound represented by the following Formula (10) is reacted with maleic anhydride in an organic solvent such as toluene in the presence of a catalyst such as toluenesulfonic acid. More specifically, after the maleimidation reaction, unreacted maleic anhydride and other impurities are removed by washing with water and the like, and the solvent is removed by reducing the pressure, whereby the maleimide compound (A) is obtained. A dehydrating agent may be used during this reaction. A commercially available product may be used as the maleimide compound (A).

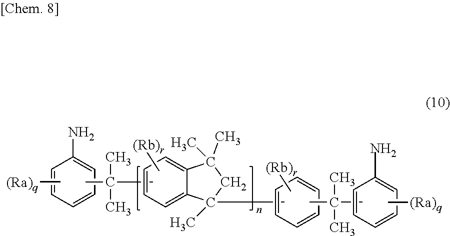

In Formula (10), Ra's are independent of each other. In other words, Ra's may be the same group as or different groups from each other, and for example, when q is 2 to 4, two to four Ra's bonded to the same benzene ring may be the same group as or different groups from each other. Ra represents an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group. Rb is the same as Rb in Formula (1), and Rb's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group. q represents 0 to 4. r represents 0 to 3. n represents 0.95 to 10.

The amine compound represented by Formula (10) is obtained by, for example, reacting 2,6-dimethylaniline with α,α′-dihydroxy-1,3-diisopropylbenzene in an organic solvent such as xylene using activated clay as a catalyst.

### (Benzoxazine Compound (B))

The benzoxazine compound (B) is not particularly limited as long as it is a benzoxazine compound having an allyl group in the molecule. The benzoxazine compound (B) has not only the allyl group but also a benzoxazine group in the molecule. Examples of the benzoxazine group include a benzoxazine group represented by the following Formula (3) and a benzoxazine group represented by the following Formula (4). Examples of the benzoxazine compound (B) include a benzoxazine compound (B1) having a benzoxazine group represented by the following Formula (3) in the molecule, a benzoxazine compound (B2) having a benzoxazine group represented by the following Formula (4) in the molecule, and a benzoxazine compound (B3) having a benzoxazine group represented by the following Formula (3) and a benzoxazine group represented by the following Formula (4) in the molecule.

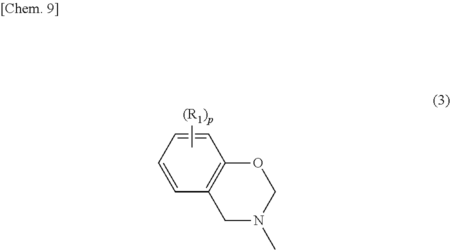

In Formula (3), R₁ represents an allyl group, and p represents 1 to 4. p is the average value of the degree of substitution of R₁, and is 1 to 4, preferably 1.

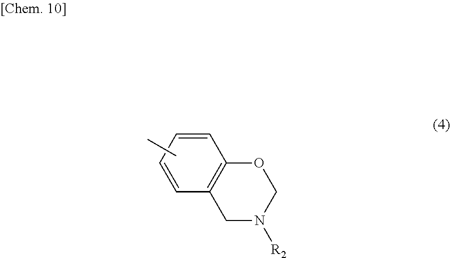

In Formula (4), R₂ represents an allyl group.

As the benzoxazine compound, specifically, the benzoxazine compound (B1) includes a benzoxazine compound (B4) represented by the following Formula (5), and the like, and it is preferable to include this benzoxazine compound (B4).

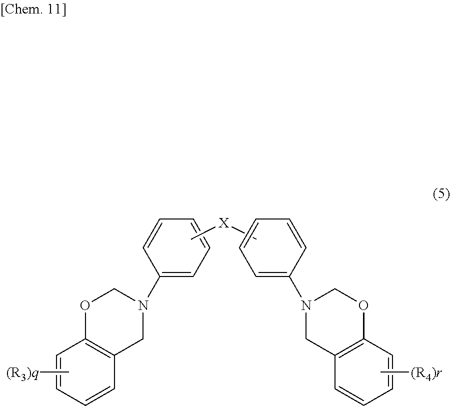

In Formula (5), R₃ and R₄ represent an allyl group, X represents an ether bond (—O—) or an alkylene group, and q and r each independently represent 1 to 4.

The alkylene group is not particularly limited, and examples thereof include a methylene group, an ethylene group, a propylene group, a butylene group, a pentylene group, a hexylene group, a heptylene group, an octane group, an icosane group, and a hexatriacontane group. Among these, a methylene group is preferable.

q is the average value of the degree of substitution of R₃, and is 1 to 4, preferably 1. r is the average value of the degree of substitution of R₄, and is 1 to 4, preferably 1.

As the benzoxazine compound (B), a commercially available product can be used, and for example, ALPd manufactured by SHIKOKU CHEMICALS CORPORATION or the like may be used.

As the benzoxazine compound (B), the benzoxazine compounds exemplified above may be used singly or in combination of two or more kinds thereof. For example, as the benzoxazine compound (B), the benzoxazine compound (B1) having a benzoxazine group represented by Formula (3) in the molecule, the benzoxazine compound (B2) having a benzoxazine group represented by Formula (4) in the molecule, and the benzoxazine compound (B3) having a benzoxazine group represented by Formula (3) and a benzoxazine group represented by Formula (4) in the molecule may each be used singly or may be used in combination of two or more kinds thereof.

### (Styrenic Polymer (C))

The styrenic polymer (C) is not particularly limited as long as it is a styrenic polymer that is solid at 25° C. Examples of the styrenic polymer (C) include styrenic polymers that are solid at 25° C. and can be used as resins contained in resin compositions used for forming insulating layers equipped in metal-clad laminates, wiring boards, and the like, and the like. The resin compositions used for forming insulating layers of metal-clad laminates, wiring boards and the like may be resin compositions used for forming resin layers of films with resin, metal foils with resin and the like, or may be a resin composition contained in prepregs.

The styrenic polymer (C) is, for example, a polymer obtained by polymerizing a monomer including a styrenic monomer, and may be a styrenic copolymer. Examples of the styrenic copolymer include: copolymers obtained by copolymerizing one or more styrenic monomers and one or more of other monomers copolymerizable with the styrenic monomers. The styrenic copolymer may be a random copolymer or a block copolymer as long as a structure derived from the styrenic monomer is included in the molecule. Examples of the block copolymer include a bipolymer of the structure (repeating unit) derived from the styrenic monomer and the other copolymerizable monomer (repeating unit) and a terpolymer of the structure (repeating unit) derived from the styrenic monomer, the other copolymerizable monomer (repeating unit), and the structure (repeating unit) derived from the styrenic monomer. The styrenic polymer (C) may be a hydrogenated styrenic copolymer obtained by hydrogenating the styrenic copolymer. The styrenic polymer (C) is preferably at least partly hydrogenated. By containing a styrenic polymer that is at least partly hydrogenated, a resin composition can be obtained which gives a cured product having a low dielectric loss tangent and a low coefficient of thermal expansion, and also excellent toughness.

The styrenic monomer is not particularly limited, but examples thereof include styrene, a styrene derivative, one in which some hydrogen atoms of the benzene ring in styrene are substituted with an alkyl group, one in which some hydrogen atoms of the vinyl group in styrene are substituted with an alkyl group, vinyltoluene, α-methylstyrene, butylstyrene, dimethylstyrene, and isopropenyltoluene. As the styrenic monomer, these may be used singly or in combination of two or more kinds thereof. The other copolymerizable monomer is not particularly limited, and examples thereof include olefins such as α-pinene, β-pinene, and dipentene, unconjugated dienes such as 1,4-hexadiene and 3-methyl-1,4-hexadiene, and conjugated dienes such as 1,3-butadiene and 2-methyl-1,3-butadiene (isoprene). As the other copolymerizable monomer, these may be used singly or in combination of two or more kinds thereof.

As the styrenic polymer (C), conventionally known ones can be widely used, the styrenic polymer (C) is not particularly limited, but examples thereof include a polymer having a structural unit represented by the following Formula (11) (a structure derived from the styrenic monomer) in the molecule.

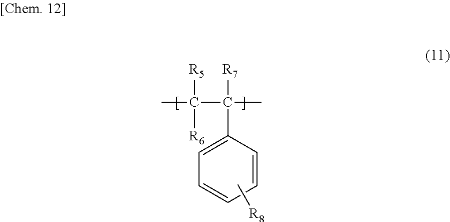

In Formula (11), R₅ to R₇ each independently represent a hydrogen atom or an alkyl group, and R₈ represents any group selected from the group consisting of a hydrogen atom, an alkyl group, an alkenyl group, and an isopropenyl group. The alkyl group is not particularly limited and is, for example, preferably an alkyl group having 1 to 18 carbon atoms, more preferably an alkyl group having 1 to 10 carbon atoms. Specific examples thereof include a methyl group, an ethyl group, a propyl group, a hexyl group, and a decyl group. The alkenyl group is preferably an alkenyl group having 1 to 10 carbon atoms.

The styrenic polymer (C) preferably contains at least one of the structural units represented by Formula (11), and may contain two or more different structural units among those represented by Formula (11) in combination. The styrenic polymer (C) may contain the structural unit represented by Formula (11) and a structural unit other than the structural unit represented by Formula (11) in combination. The styrenic polymer (C) may contain a structure in which the structural unit represented by Formula (11) is repeated.

In addition to the structural unit represented by Formula (11), the styrenic polymer (C) may have at least one among structural units represented by the following Formula (12), the following Formula (13), and the following Formula (14) and structures in which structural units represented by the following Formula (12), the following Formula (13), and the following Formula (14) are each repeated as a structural unit derived from another monomer that is copolymerizable with the styrenic monomer.

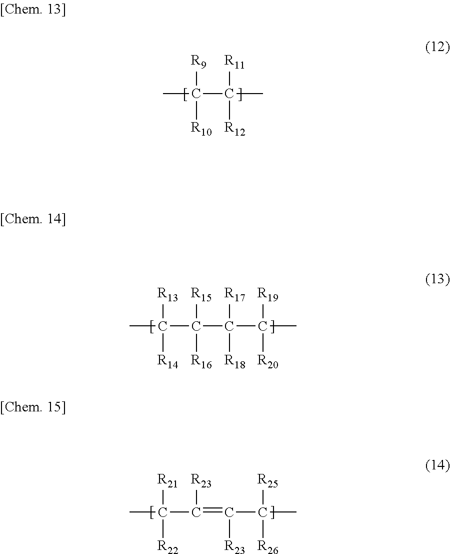

In Formula (12), Formula (13), and Formula (14), R₉ to R₂₆ each independently represent any group selected from the group consisting of a hydrogen atom, an alkyl group, an alkenyl group, and an isopropenyl group. The alkyl group is not particularly limited and is, for example, preferably an alkyl group having 1 to 18 carbon atoms, more preferably an alkyl group having 1 to 10 carbon atoms. Specific examples thereof include a methyl group, an ethyl group, a propyl group, a hexyl group, and a decyl group. The alkenyl group is preferably an alkenyl group having 1 to 10 carbon atoms.

The styrenic polymer (C) preferably contains at least one among the structural units represented by Formula (12), Formula (13), and Formula (14), and may contain two or more different structural units among these in combination. The styrenic polymer may have at least one among the structures in which the structural units represented by Formula (12), Formula (13), and Formula (14) are each repeated.

More specific examples of the structural unit represented by Formula (11) include structural units represented by the following Formulas (15) to (17). The structural unit represented by Formula (11) may be structures in which structural units represented by the following Formulas (15) to (17) are each repeated, and the like. The structural unit represented by Formula (11) may be one structural unit among these or a combination of two or more different structural units.

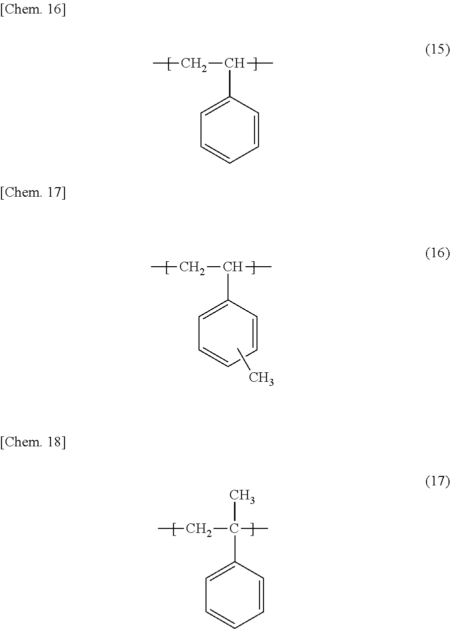

More specific examples of the structural unit represented by Formula (12) include structural units represented by the following Formulas (18) to (24). The structural unit represented by Formula (12) may be structures in which structural units represented by the following Formulas (18) to (24) are each repeated, and the like. The structural unit represented by Formula (12) may be one structural unit among these or a combination of two or more different structural units.

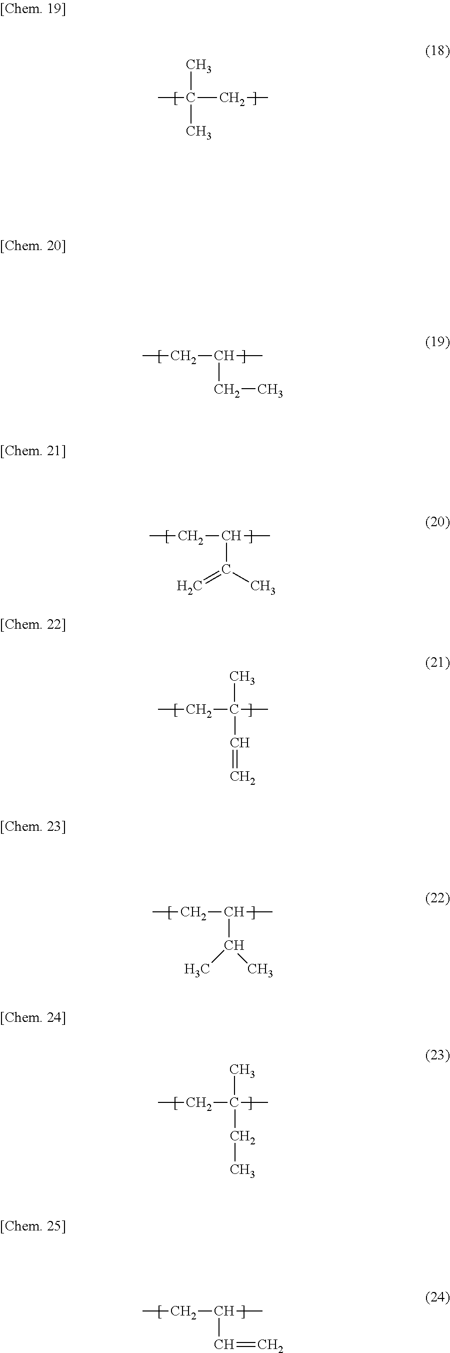

More specific examples of the structural unit represented by Formula (13) include structural units represented by the following Formulas (25) and (26). The structural unit represented by Formula (13) may be structures in which structural units represented by the following Formulas (27) and (28) are each repeated, and the like. The structural unit represented by Formula (13) may be one structural unit among these or a combination of two or more different structural units.

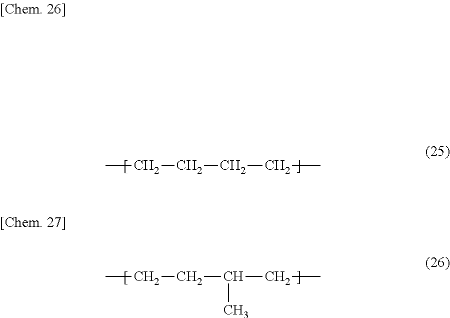

More specific examples of the structural unit represented by Formula (14) include structural units represented by the following Formulas (27) and (28). The structural unit represented by Formula (14) may be structures in which structural units represented by the following Formulas (27) and (28) are each repeated, and the like. The structural unit represented by Formula (14) may be one structural unit among these or a combination of two or more different structural units.

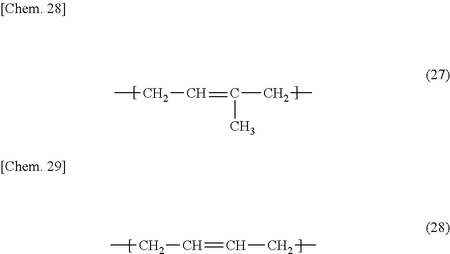

Preferred examples of the styrenic copolymer (C) include polymers or copolymers obtained by polymerizing or copolymerizing one or more styrenic monomers such as styrene, vinyltoluene, α-methylstyrene, isopropenyltoluene, divinylbenzene, or allylstyrene.

More specific examples of the styrenic polymer (C) include a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a styrene butadiene block copolymer such as a styrene butadiene styrene block copolymer, a styrene isobutylene styrene block copolymer, a styrene (butadiene/butylene) styrene block copolymer, and hydrogenated products in which these are at least partly hydrogenated.

As the styrenic polymer (C), a commercially available product can be used, and for example, Tuftec P1500, Tuftec H1041, and Tuftec H1517 manufactured by Asahi Kasei Corporation and Asaprene T437 manufactured by Asahi Kasei Corporation may be used.

As the styrenic polymer (C), the styrenic polymers exemplified above may be used singly or in combination of two or more kinds thereof.

The weight average molecular weight of the styrenic polymer (C) is preferably 1,000 to 300,000, more preferably 10,000 to 200,000. When the molecular weight is too low, the glass transition temperature or heat resistance of the cured product of the resin composition tends to decrease. When the molecular weight is too high, the viscosity of the resin composition when prepared in the form of a varnish and the viscosity of the resin composition during heat molding tend to be too high. The weight average molecular weight is only required to be one measured by a general molecular weight measurement method, and specific examples thereof include a value measured by gel permeation chromatography (GPC).

### (Inorganic Filler)

The resin composition may contain an inorganic filler, if necessary, as long as the effects of the present invention are not impaired. It is preferable to contain the inorganic filler from the viewpoint of enhancing the heat resistance and the like of the cured product of the resin composition. The inorganic filler is not particularly limited as long as it is an inorganic filler that can be used as an inorganic filler contained in a resin composition. Examples of the inorganic filler include a silica filler, metal oxide fillers such as an alumina filler, a titanium oxide filler, a magnesium oxide filler, and a mica filler, metal hydroxide fillers such as a magnesium hydroxide filler and an aluminum hydroxide filler, a talc filler, an aluminum borate filler, a barium sulfate filler, an aluminum nitride filler, a boron nitride filler, a barium titanate filler, a strontium titanate filler, a calcium titanate filler, magnesium carbonate fillers such as an anhydrous magnesium carbonate filler, a calcium carbonate filler, and molybdate fillers such as a zinc molybdate filler, a calcium molybdate filler, and a magnesium molybdate filler. Among them, a silica filler, metal hydroxide fillers such as a magnesium hydroxide filler and an aluminum hydroxide filler, an aluminum oxide filler, a boron nitride filler, a strontium titanate filler, a calcium titanate filler, molybdate fillers and the like are preferable, and a silica filler and a zinc molybdate filler are more preferable. The silica filler is not particularly limited, examples thereof include crushed silica, spherical silica, and silica particles, and spherical silica is preferable. The inorganic filler may be used singly or in combination of two or more kinds thereof. When two or more inorganic fillers are used in combination, a silica filler and a zinc molybdate filler are preferably used in combination.

The inorganic filler may be an inorganic filler subjected to a surface treatment or an inorganic filler not subjected to a surface treatment. Examples of the surface treatment include treatment with a silane coupling agent.

The silane coupling agent is not particularly limited, and examples thereof include a silane coupling agent having at least one functional group selected from the group consisting of a vinyl group, a styryl group, a methacryloyl group, an acryloyl group, a phenylamino group, an isocyanurate group, a ureido group, a mercapto group, an isocyanate group, an epoxy group, and an acid anhydride group. In other words, examples of this silane coupling agent include compounds having at least one of a vinyl group, a styryl group, a methacryloyl group, an acryloyl group, a phenylamino group, an isocyanurate group, a ureido group, a mercapto group, an isocyanate group, an epoxy group, and an acid anhydride group as a reactive functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilane and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the inorganic filler is not particularly limited, and is preferably 0.05 to 10 μm and more preferably 0.1 to 8 μm. Here, the average particle size refers to the volume average particle size. The volume average particle size can be measured by, for example, a laser diffraction method and the like.

### (Content)

The content of the maleimide compound (A) is preferably 30 to 80 parts by mass, more preferably 35 to 65 parts by mass with respect to 100 parts by mass of the sum of the maleimide compound (A) and the benzoxazine compound (B). When the content of the maleimide compound (A) is within the above range, a resin composition that can give a cured product having a low coefficient of thermal expansion and high plating adhesion is more suitably obtained. This is considered to be due to the fact that each of the effect exhibited by containing the maleimide compound (A) and the effect exhibited by containing the benzoxazine compound (B) can be fully exerted when the content of the maleimide compound (A) is in the above range.

The content of the maleimide compound (A) is preferably 20 to 60 parts by mass, more preferably 40 to 60 parts by mass with respect to 100 parts by mass of the sum of the maleimide compound (A), the benzoxazine compound (B), and the styrenic polymer (C).

The content of the benzoxazine compound (B) is preferably 20 to 40 parts by mass, more preferably 25 to 35 parts by mass with respect to 100 parts by mass of the sum of the maleimide compound (A), the benzoxazine compound (B), and the styrenic polymer (C).

The content of the styrenic polymer (C) is preferably 15 to 40 parts by mass, more preferably 25 to 40 parts by mass with respect to 100 parts by mass of the sum of the maleimide compound (A), the benzoxazine compound (B), and the styrenic polymer (C).

When the contents of the maleimide compound (A), the benzoxazine compound (B), and the styrenic polymer (C) are within the above ranges, a resin composition that can give a cured product having a low coefficient of thermal expansion and high plating adhesion is more suitably obtained. This is considered to be due to the fact that each of the effect exhibited by containing the maleimide compound (A), the effect exhibited by containing the benzoxazine compound (B), and the effect exhibited by containing the styrenic polymer (C) can be fully exerted when the contents of the maleimide compound (A), the benzoxazine compound (B), and the styrenic polymer (C) are within the above ranges.

The resin composition may contain the inorganic filler as described above. When the resin composition contains the inorganic filler, the content of the inorganic filler is preferably 50 to 250 parts by mass, more preferably 100 to 200 parts by mass with respect to 100 parts by mass of the sum of the maleimide compound (A), the benzoxazine compound (B), and the styrenic polymer (C).

### (Organic Component)

The resin composition according to the present embodiment may contain an organic component other than the maleimide compound (A), the benzoxazine compound (B), and the styrenic polymer (C), if necessary, as long as the effects of the present invention are not impaired. Here, the organic component may or may not react with at least any one of the maleimide compound (A), the benzoxazine compound (B), or the styrenic polymer (C). Examples of the organic component include a maleimide compound (D) different from the maleimide compound (A), a benzoxazine compound (E) different from the benzoxazine compound (B), an epoxy compound, a methacrylate compound, an acrylate compound, a vinyl compound, a cyanate ester compound, an active ester compound, and an allyl compound. That is, the resin composition may further contain an organic component other than the maleimide compound (A), the benzoxazine compound (B), and the styrenic polymer (C), and the organic component may include at least one selected from the group consisting of a maleimide compound (D) different from the maleimide compound (A), a benzoxazine compound (E) different from the benzoxazine compound (B), an epoxy compound, a methacrylate compound, an acrylate compound, a vinyl compound, a cyanate ester compound, an active ester compound, and an allyl compound.

The maleimide compound (D) is a maleimide compound that has a maleimide group in the molecule but does not have an indane structure represented by Formula (1) in the molecule. Examples of the maleimide compound (D) include a maleimide compound having one or more maleimide groups in the molecule, and a modified maleimide compound. The maleimide compound (D) is not particularly limited as long as it has one or more maleimide groups in the molecule but does not have an indane structure represented by Formula (1) in the molecule. Examples of the maleimide compound (D) include phenylmaleimide compounds such as 4,4′-diphenylmethanebismaleimide, phenylmethanemaleimide, m-phenylenebismaleimide, bisphenol A diphenyl ether bismaleimide, 3,3′-dimethyl-5,5′-diethyl-4,4′-diphenylmethanebismaleimide, 4-methyl-1,3-phenylenebismaleimide, and a biphenylaralkyl type polymaleimide compound, and an N-alkyl bismaleimide compound having an aliphatic skeleton. Examples of the modified maleimide compound include a modified maleimide compound in which a part of the molecule is modified with an amine compound and a modified maleimide compound in which a part of the molecule is modified with a silicone compound. As the maleimide compound (D), a commercially available product can also be used, and for example, the solid component in MIR-3000-70MT and the solid component in MIR-5000-60T1 manufactured by Nippon Kayaku Co., Ltd., BMI-2300, BMI-4000 and BMI-5100 manufactured by Daiwa Kasei Industry Co., Ltd., and BMI-689, BMI-1500, BMI-3000J and BMI-5000 manufactured by Designer Molecules Inc. may be used.

The benzoxazine compound (E) is a benzoxazine compound other than the benzoxazine compound (B) [the benzoxazine compound (B1) (the benzoxazine compound (B4) and the like), the benzoxazine compound (B2), the benzoxazine compound (B3), and the like]. The benzoxazine compound (E) is not particularly limited as long as it is a benzoxazine compound that has a benzoxazine group in the molecule and is other than the benzoxazine compound (B). Examples of the benzoxazine compound (E) include benzoxazine compounds having a phenolphthalein structure in the molecule (phenolphthalein-type benzoxazine compounds), bisphenol F-type benzoxazine compounds, and diaminodiphenylmethane (DDM)-type benzoxazine compounds. More specific examples of the other benzoxazine compound include 3,3′-(methylene-1,4-diphenylene)bis(3,4-dihydro-2H-1,3-benzoxazine) (P-d type benzoxazine compound), 2,2-bis(3,4-dihydro-2H-3-phenyl-1,3-benzoxazine)methane (F-a type benzoxazine compound), and oxydianiline (ODA)-type benzoxazine.

The epoxy compound is a compound having an epoxy group in the molecule, and specific examples thereof include a bisphenol type epoxy compound such as a bisphenol A type epoxy compound, a phenol novolac type epoxy compound, a cresol novolac type epoxy compound, a dicyclopentadiene type epoxy compound, a bisphenol A novolac type epoxy compound, a biphenylaralkyl type epoxy compound, and a naphthalene ring-containing epoxy compound. The epoxy compound also includes an epoxy resin, which is a polymer of each of the epoxy compounds.

The methacrylate compound is a compound having a methacryloyl group in the molecule, and examples thereof include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate (DCP).

The acrylate compound is a compound having an acryloyl group in the molecule, and examples thereof include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The vinyl compound is a compound having a vinyl group in the molecule, and examples thereof include a monofunctional vinyl compound (monovinyl compound) having one vinyl group in the molecule and a polyfunctional vinyl compound having two or more vinyl groups in the molecule. Examples of the polyfunctional vinyl compound include divinylbenzene, a curable polybutadiene having a carbon-carbon unsaturated double bond in the molecule, a butadiene-styrene copolymer other than the styrenic polymer, a polyphenylene ether compound having a vinylbenzyl group (ethenylbenzyl group) at the terminal, and modified polyphenylene ether obtained by modifying the terminal hydroxyl group of polyphenylene ether with a methacryl group. Examples of the butadiene-styrene copolymer other than the styrenic polymer include a curable butadiene-styrene copolymer having a carbon-carbon unsaturated double bond in the molecule and being liquid at 25° C., a curable butadiene-styrene random copolymer having a carbon-carbon unsaturated double bond in the molecule, and a curable butadiene-styrene random copolymer having a carbon-carbon unsaturated double bond in the molecule and being liquid at 25° C.

The cyanate ester compound is a compound having a cyanato group in the molecule, and examples thereof include 2,2-bis(4-cyanatophenyl)propane, bis(3,5-dimethyl-4-cyanatophenyl)methane, and 2,2-bis(4-cyanatophenyl)ethane.

The active ester compound is a compound having an ester group exhibiting high reaction activity in the molecule, and examples thereof include a benzenecarboxylic acid active ester, a benzenedicarboxylic acid active ester, a benzenetricarboxylic acid active ester, a benzenetetracarboxylic acid active ester, a naphthalenecarboxylic acid active ester, a naphthalenedicarboxylic acid active ester, a naphthalenetricarboxylic acid active ester, a naphthalenetetracarboxylic acid active ester, a fluorenecarboxylic acid active ester, a fluorenedicarboxylic acid active ester, a fluorenetricarboxylic acid active ester, and a fluorenetetracarboxylic acid active ester.

The allyl compound is a compound having an allyl group in the molecule, and examples thereof include a triallyl isocyanurate compound such as triallyl isocyanurate (TAIC), a diallyl bisphenol compound, an allyl epoxy compound, and diallyl phthalate (DAP).

As the organic component, the organic components described above may be used singly or in combination of two or more kinds thereof.

The weight average molecular weight of the organic component is not particularly limited, and is, for example, preferably 100 to 5000, more preferably 100 to 4000, still more preferably 100 to 3000. When the weight average molecular weight of the organic component is too low, there is a risk that the organic component easily volatilizes from the blended component system of the resin composition. When the weight average molecular weight of the organic component is too high, the viscosity of the varnish of the resin composition and the melt viscosity at the time of heat molding become too high, and there is a risk of deterioration in appearance and moldability when the resin composition is brought into B stage. Hence, a resin composition imparting superior heat resistance and moldability to its cured product is obtained when the weight average molecular weight of the organic component is in such a range. It is considered that this is because the resin composition can be suitably cured. Here, the weight average molecular weight may be measured by a general molecular weight measurement method, and specific examples thereof include a value measured by gel permeation chromatography (GPC).

In the organic component, the average number (number of functional groups) of the functional groups, which contribute to the reaction during curing of the resin composition, per one molecule of the organic component varies depending on the weight average molecular weight of the organic component but is, for example, preferably 1 to 20, more preferably 2 to 18. When this number of functional groups is too small, sufficient heat resistance of the cured product tends to be hardly attained. When the number of functional groups is too large, the reactivity is too high and, for example, troubles such as a decrease in the storage stability of the resin composition or a decrease in the fluidity of the resin composition may occur.

### (Other Components)

The resin composition may contain components (other components) other than the maleimide compound (A) and the benzoxazine compound (B) as long as the effects of the present invention are not impaired. As described above, the resin composition may contain the styrenic polymer (C), the inorganic filler, and the organic component as the other components. Examples of the other components other than the styrenic polymer (C), the inorganic filler, and the organic component include additives such as a flame retardant, a reaction initiator, a curing accelerator, a catalyst, a polymerization retarder, a polymerization inhibitor, a dispersant, a leveling agent, a coupling agent, an antifoaming agent, an antioxidant, a heat stabilizer, an antistatic agent, an ultraviolet absorber, a dye or a pigment, and a lubricant.

As described above, the resin composition according to the present embodiment may contain a flame retardant. The flame retardancy of a cured product of the resin composition can be enhanced by containing a flame retardant. The flame retardant is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene that have a melting point of 300° C. or more, and a bromostyrene-based compound that reacts with the polymerizable compound are preferable. It is considered that the elimination of halogen at a high temperature and the decrease in heat resistance can be suppressed by the use of a halogen-based flame retardant. There is a case where a flame retardant containing phosphorus (phosphorus-based flame retardant) is used in fields required to be halogen-free. The phosphorus-based flame retardant is not particularly limited, and examples thereof include a phosphate ester-based flame retardant, a phosphazene-based flame retardant, a bis(diphenylphosphine oxide)-based flame retardant, a 9,10-dihydro-9-oxa-10-phosphaphenanthrene-10-oxide (DOPO)-based flame retardant, and a phosphinate salt-based flame retardant. Specific examples of the phosphate ester-based flame retardant include a condensed phosphate ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the DOPO-based flame retardant include hydrocarbons having two DOPO groups in the molecule (DOPO derivative compounds). Specific examples of the phosphinate-based flame retardant include metal phosphinates such as an aluminum dialkyl phosphinate. As the flame retardant, the respective flame retardants exemplified may be used singly or in combination of two or more kinds thereof.

As described above, the resin composition according to the present embodiment may contain a reaction initiator. The reaction initiator is not particularly limited as long as it can promote the curing reaction of the resin composition, and examples thereof include a peroxide and an organic azo compound. Examples of the peroxide include α,α′-di(t-butylperoxy)diisopropylbenzene (PBP), 2,5-dimethyl-2,5-di(t-butylperoxy)-3-hexyne, and benzoyl peroxide. Examples of the organic azo compound include azobisisobutyronitrile. A metal carboxylate can be concurrently used if necessary. By doing so, the curing reaction can be further promoted. Among these, α,α′-di(t-butylperoxy)diisopropylbenzene is preferably used. α,α′-Di(t-butylperoxy)diisopropylbenzene has a relatively high reaction initiation temperature and thus can suppress the promotion of the curing reaction at the time point at which curing is not required, for example, at the time of prepreg drying, and can suppress a decrease in storage stability of the resin composition. α,α′-Di(t-butylperoxy)diisopropylbenzene exhibits low volatility, and thus does not volatilize at the time of prepreg drying and storage, and exhibits favorable stability. The reaction initiators may be used singly or in combination of two or more kinds thereof.

As described above, the resin composition according to the present embodiment may contain a curing accelerator. The curing accelerator is not particularly limited as long as it can promote the curing reaction of the resin composition. Specific examples of the curing accelerator include imidazoles and derivatives thereof, organophosphorus compounds, amines such as secondary amines and tertiary amines, quaternary ammonium salts, organoboron compounds, and metal soaps. Examples of the imidazoles include 2-ethyl-4-methylimidazole (2E4MZ), 2-methylimidazole, 2-phenyl-4-methylimidazole, 2-phenylimidazole, and 1-benzyl-2-methylimidazole. Examples of the organophosphorus compounds include triphenylphosphine, diphenylphosphine, phenylphosphine, tributylphosphine, and trimethylphosphine. Examples of the amines include dimethylbenzylamine, triethylenediamine, triethanolamine, and 1,8-diaza-bicyclo(5,4,0)undecene-7 (DBU). Examples of the quaternary ammonium salts include tetrabutylammonium bromide. Examples of the organoboron compounds include tetraphenylboron salts such as 2-ethyl-4-methylimidazole-tetraphenylborate and tetra-substituted phosphonium/tetra-substituted borate such as tetraphenylphosphonium/ethyltriphenylborate. The metal soap refers to a fatty acid metal salt, and may be a linear fatty acid metal salt or a cyclic fatty acid metal salt. Specific examples of the metal soaps include linear aliphatic metal salts and cyclic aliphatic metal salts having 6 to 10 carbon atoms. More specific examples thereof include aliphatic metal salts formed from linear fatty acids such as stearic acid, lauric acid, ricinoleic acid, and octylic acid and cyclic fatty acids such as naphthenic acid and metals such as lithium, magnesium, calcium, barium, copper, and zinc. Examples thereof include zinc octylate. The curing accelerators may be used singly or in combination of two or more kinds thereof.

As described above, the resin composition according to the present embodiment may contain a silane coupling agent. The silane coupling agent may be contained in the resin composition or may be contained as a silane coupling agent covered on the inorganic filler contained in the resin composition for surface treatment in advance. Among them, it is preferable that the silane coupling agent is contained as a silane coupling agent covered on the inorganic filler for surface treatment in advance, and it is more preferable that the silane coupling agent is contained as a silane coupling agent covered on the inorganic filler for surface treatment in advance and further is also contained in the resin composition. In the case of a prepreg, the silane coupling agent may be contained in the prepreg as a silane coupling agent covered on the fibrous base material for surface treatment in advance. Examples of the silane coupling agent include those similar to the silane coupling agents used in the surface treatment of the inorganic filler described above.

The resin composition according to the present embodiment is a resin composition, which affords a cured product having a low coefficient of thermal expansion and high plating adhesion. Further, in order to suppress loss due to increased resistance accompanying refinement of wiring, the insulating layers equipped in wiring boards are also required to have lower dielectric properties such as dielectric loss tangent. The resin composition is a resin composition, which affords a cured product having not only a low coefficient of thermal expansion and high plating adhesion, but also a low dielectric loss tangent.

Wiring boards used in various electronic devices are also required to be hardly affected by changes in the external environment. Substrate materials for forming insulating layers of wiring boards are required to afford cured products exhibiting superior heat resistance such as a high glass transition temperature so that the wiring boards can be used under relatively high temperature conditions. It is also required that insulating layers of wiring boards do not deform even in a relatively high temperature environment. Since this deformation is suppressed when the glass transition temperature of insulating layers is high, the substrate materials for forming insulating layers of wiring boards are required to have a high glass transition temperature. The resin composition according to the present embodiment is a resin composition, which affords a cured product having not only a low coefficient of thermal expansion and high plating adhesion, but also a high glass transition temperature.

In electronic devices, particularly in small portable devices such as portable communication terminals and notebook computers, diversification, improvement in performance, thinning, and miniaturization have rapidly proceeded. Along with this, in wiring boards used in these products as well, there is a further demand for refinement of conductor wiring, multilayering of conductor wiring layers, thinning, and improvement in performance such as mechanical properties. For this reason, in the wiring boards, it is also required that the wirings do not peel off from the insulating layers although provided wirings are refined wirings. In order to meet this requirement, in the wiring boards, it is required that the adhesion between wirings and insulating layers is high. Hence, it is required that the adhesion between metal foils and insulating layers is high in metal-clad laminates, and substrate materials for forming insulating layers of wiring boards are required to afford cured products exhibiting excellent adhesion to metal foils. As described above, wiring boards are required to be multi-layered and are also required to exhibit high interlayer adhesion so that delamination between an insulating layer and another insulating layer does not occur when insulating layers are constituted of multiple layers. For this reason, substrate materials for forming insulating layers of the wiring boards are required to afford cured products, which are excellent in adhesion between adjacent cured products, namely, interlayer adhesion. The resin composition according to the present embodiment is a resin composition, which affords a cured product having not only a low coefficient of thermal expansion and high plating adhesion, but also excellent adhesion to a metal foil and interlayer adhesion.

Insulating layers of wiring boards used in various electronic devices are also required to be capable of appropriately performing electroless plating and electrolytic plating after removing smear generated by the drilling when drilling is performed using a drill, laser, or the like, as described above. Specifically, insulating layers of wiring boards are required to exert excellent desmear properties (e.g., smear can be properly removed with permanganic acid or the like while damage to the insulating layers of wiring boards is suppressed). Hence, substrate materials for forming insulating layers of wiring boards are required to afford cured products exhibiting excellent desmear properties. The resin composition according to the present embodiment is a resin composition, which affords a cured product not only having a low coefficient of thermal expansion and high plating adhesion, but also exhibiting excellent desmear properties.

The resin composition according to the present embodiment is a resin composition, which affords a cured product having a low coefficient of thermal expansion and high plating adhesion. Furthermore, the resin composition according to the present embodiment is a resin composition, which affords a cured product having not only a low coefficient of thermal expansion and high plating adhesion but also a low dielectric loss tangent, a high glass transition temperature, and excellent adhesion to a metal foil, interlayer adhesion, and desmear properties.

### (Use)

The resin composition is used when a prepreg is manufactured, as described later. The resin composition is used when a resin layer included in a metal foil with resin and a film with resin is formed and when an insulating layer included in a metal-clad laminate and a wiring board is formed.

### (Production Method)

The method for producing the resin composition is not particularly limited, and examples thereof include a method in which the maleimide compound (A), the benzoxazine compound (B), the styrenic polymer (C), and if necessary, components other than the maleimide compound (A), the benzoxazine compound (B), and the styrenic polymer (C) are mixed together so as to have predetermined contents. Examples thereof include the method to be described later in the case of obtaining a varnish-like composition containing an organic solvent.

[Prepreg, Metal-Clad Laminate, Wiring Board, Metal Foil with Resin, and Film with Resin]

By using the resin composition according to the present embodiment, a prepreg, a metal-clad laminate, a wiring board, a metal foil with resin, and a film with resin can be obtained as described below.

### (Prepreg)

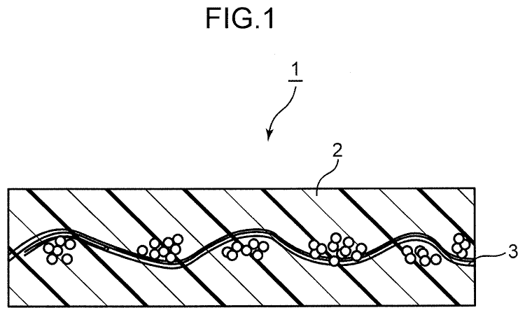

FIG. 1 is a schematic sectional view illustrating an example of a prepreg 1 according to an embodiment of the present invention.

As illustrated in FIG. 1, the prepreg 1 according to the present embodiment includes the resin composition or a semi-cured product 2 of the resin composition and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, semi-curing includes the state between after the viscosity starts to increase and before the resin composition is completely cured.

The prepreg obtained using the resin composition according to the present embodiment may include a semi-cured product of the resin composition as described above, or may include the uncured resin composition itself. In other words, the prepreg may be a prepreg including a semi-cured product of the resin composition (the resin composition in B stage) and a fibrous base material or a prepreg including the resin composition before being cured (the resin composition in A stage) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components which can be dissolved in an organic solvent are introduced into and dissolved in an organic solvent. At this time, heating may be performed if necessary. Thereafter, components which are used if necessary but are not dissolved in the organic solvent are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the maleimide compound (A), the benzoxazine compound (B), and the styrenic polymer (C), and the like and does not inhibit the curing reaction. Specific examples thereof include toluene and methyl ethyl ketone (MEK).

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less. The glass fiber constituting the glass cloth is not particularly limited, and examples thereof include Q glass, NE glass, E glass, S glass, T glass, L glass, and L2 glass. The surface of the fibrous base material may be subjected to a surface treatment with a silane coupling agent. The silane coupling agent is not particularly limited, and examples thereof include a silane coupling agent having at least one selected from the group consisting of a vinyl group, an acryloyl group, a methacryloyl group, a styryl group, an amino group, and an epoxy group in the molecule.

The method for manufacturing the prepreg is not particularly limited as long as the prepreg can be manufactured. Specifically, when the prepreg is manufactured, the resin composition according to the present embodiment described above is often prepared in a varnish form and used as a resin varnish as described above.

Specific examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 40° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

### (Metal-Clad Laminate)

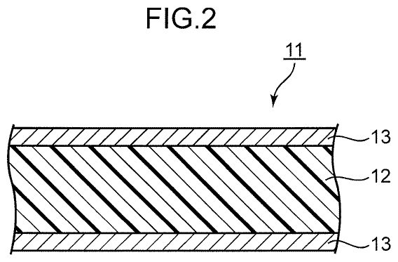

FIG. 2 is a schematic sectional view illustrating an example of a metal-clad laminate 11 according to an embodiment of the present invention.

As illustrated in FIG. 2, the metal-clad laminate 11 according to the present embodiment includes an insulating layer 12 containing a cured product of the resin composition and a metal foil 13 provided on the insulating layer 12. Examples of the metal-clad laminate 11 include a metal-clad laminate including an insulating layer 12 containing a cured product of the prepreg 1 illustrated in FIG. 1 and a metal foil 13 to be laminated together with the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the resin composition contained in the prepreg 1, and the like. For example, it is possible to set the temperature to 170 to 230° C., the pressure to 0.5 to 5 MPa, and the time to 60 to 150 minutes. The metal-clad laminate may be manufactured without using a prepreg. Examples thereof include a method in which a varnish-like resin composition is applied on a metal foil to form a layer containing the resin composition on the metal foil and then heating and pressing is performed.

### (Wiring Board)

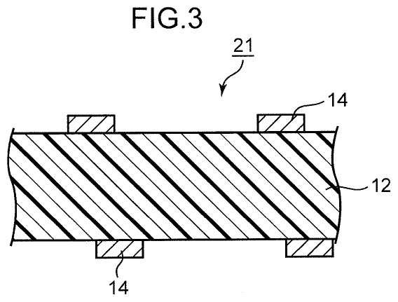

FIG. 3 is a schematic sectional view illustrating an example of a wiring board 21 according to an embodiment of the present invention.

As illustrated in FIG. 3, the wiring board 21 according to the present embodiment includes an insulating layer 12 containing a cured product of the resin composition and wiring 14 provided on the insulating layer 12. Examples of the wiring board 21 include a wiring board formed of an insulating layer 12 obtained by curing the prepreg 1 illustrated in FIG. 1 and wiring 14 which is laminated together with the insulating layer 12 and is formed by partially removing the metal foil 13. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above.

(Metal Foil with Resin)

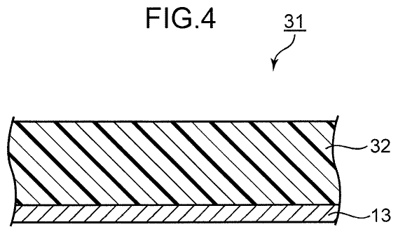

FIG. 4 is a schematic sectional view illustrating an example of a metal foil with resin 31 according to the present embodiment.

The metal foil with resin 31 according to the present embodiment includes a resin layer 32 containing the resin composition or a semi-cured product of the resin composition and a metal foil 13 as illustrated in FIG. 4. The metal foil with resin 31 includes the metal foil 13 on the surface of the resin layer 32. In other words, the metal foil with resin 31 includes the resin layer 32 and the metal foil 13 to be laminated together with the resin layer 32. The metal foil with resin 31 may include other layers between the resin layer 32 and the metal foil 13.

The resin layer 32 may contain a semi-cured product of the resin composition as described above or may contain the uncured resin composition. In other words, the metal foil with resin 31 may be a metal foil with resin including a resin layer containing a semi-cured product of the resin composition (the resin composition in B stage) and a metal foil or a metal foil with resin including a resin layer containing the resin composition before being cured (the resin composition in A stage) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils used in metal-clad laminates or metal foils with resin can be used without limitation. Examples of the metal foil include a copper foil and an aluminum foil.

The metal foil with resin 31 may include a cover film and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 31 is not particularly limited as long as the metal foil with resin 31 can be manufactured. Examples of the method for manufacturing the metal foil with resin 31 include a method in which the varnish-like resin composition (resin varnish) is applied on the metal foil 13 and heated to manufacture the metal foil with resin 31. The varnish-like resin composition is applied on the metal foil 13 using, for example, a bar coater. The applied resin composition is heated under the conditions of, for example, 40° C. or more and 180° C. or less and 0.1 minute or more and 10 minutes or less. The heated resin composition is formed as the uncured resin layer 32 on the metal foil 13. By the heating, the organic solvent can be decreased or removed by being volatilized from the resin varnish.

(Film with Resin)

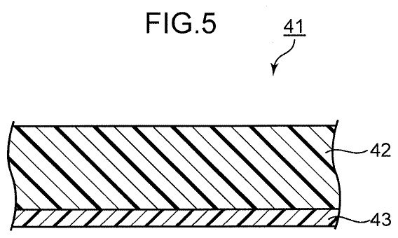

FIG. 5 is a schematic sectional view illustrating an example of a film with resin 41 according to the present embodiment.

The film with resin 41 according to the present embodiment includes a resin layer 42 containing the resin composition or a semi-cured product of the resin composition and a support film 43 as illustrated in FIG. 5. The film with resin 41 includes the resin layer 42 and the support film 43 to be laminated together with the resin layer 42. The film with resin 41 may include other layers between the resin layer 42 and the support film 43.

The resin layer 42 may contain a semi-cured product of the resin composition as described above or may contain the uncured resin composition. In other words, the film with resin 41 may be a film with resin including a resin layer containing a semi-cured product of the resin composition (the resin composition in B stage) and a support film or a film with resin including a resin layer containing the resin composition before being cured (the resin composition in A stage) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the support film 43, support films used in films with resin can be used without limitation. Examples of the support film include electrically insulating films such as a polyester film, a polyethylene terephthalate (PET) film, a polyimide film, a polyparabanic acid film, a polyether ether ketone film, a polyphenylene sulfide film, a polyamide film, a polycarbonate film, and a polyarylate film.

The film with resin 41 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 41 is not particularly limited as long as the film with resin 41 can be manufactured. Examples of the method for manufacturing the film with resin 41 include a method in which the varnish-like resin composition (resin varnish) is applied on the support film 43 and heated to manufacture the film with resin 41. The varnish-like resin composition is applied on the support film 43 using, for example, a bar coater. The applied resin composition is heated under the conditions of, for example, 40° C. or more and 180° C. or less and 0.1 minute or more and 10 minutes or less. The heated resin composition is formed as the uncured resin layer 42 on the support film 43. By the heating, the organic solvent can be decreased or removed by being volatilized from the resin varnish.

When cured, the resin composition according to the present embodiment becomes a cured product having a low coefficient of thermal expansion and high plating adhesion. Therefore, when cured, the prepreg becomes a cured product having a low coefficient of thermal expansion and high plating adhesion. The metal foil with resin and the film with resin are a metal foil with resin and a film with resin each including a resin layer that becomes an insulating layer containing the cured product are obtained when cured. The metal-clad laminate and the wiring board are a metal-clad laminate and a wiring board each including an insulating layer containing the cured product. The prepreg, the film with resin, the metal foil with resin, and the metal-clad laminate can be used when the wiring board is suitably manufactured, and can also be used, for example, when a multilayer wiring board is manufactured. A multilayer wiring board can be manufactured, for example, by laminating the film with resin on a wiring board and then peeling off the support film from the film with resin or by peeling off the support film from the film with resin and then laminating the film with resin on a wiring board. For example, by laminating the metal foil with resin on a wiring board, a multilayer wiring board can be manufactured. As described above, the multilayer wiring board including the insulating layer containing the cured product can be manufactured by using the film with resin, the metal foil with resin, and the like.

This specification discloses technologies in various aspects as described above, and the main technologies among these are summarized below.

A resin composition according to a first aspect of the present invention is a resin composition containing a maleimide compound (A) having an indane structure represented by the following Formula (1) in a molecule, a benzoxazine compound (B) having an allyl group in a molecule, and a styrenic polymer (C) that is solid at 25° C.

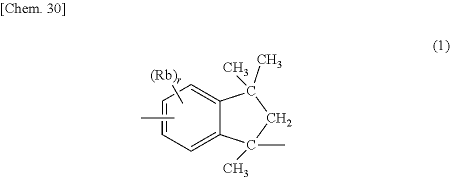

In Formula (1), Rb's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group, and r represents 0 to 3.

A resin composition according to a second aspect of the present invention is the resin composition according to the first aspect, in which the maleimide compound (A) includes a maleimide compound (A1) represented by the following Formula (2).

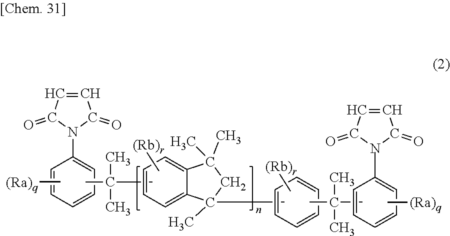

In Formula (2), Ra's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group, Rb's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group, q represents 0 to 4, r represents 0 to 3, and n represents 0.95 to 10.

A resin composition according to a third aspect of the present invention is the resin composition according to the first or second aspect of the present invention, in which the benzoxazine compound (B) includes at least one selected from the group consisting of a benzoxazine compound (B1) having a benzoxazine group represented by the following Formula (3) in a molecule, a benzoxazine compound (B2) having a benzoxazine group represented by the following Formula (4) in a molecule, or a benzoxazine compound (B3) having a benzoxazine group represented by the following Formula (3) and a benzoxazine group represented by the following Formula (4) in a molecule.

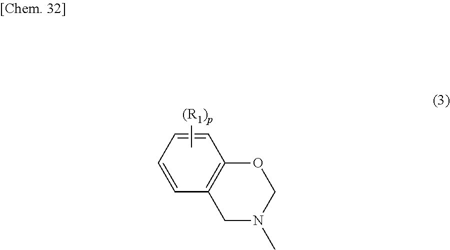

In Formula (3), R₁ represents an allyl group, and p represents 1 to 4.

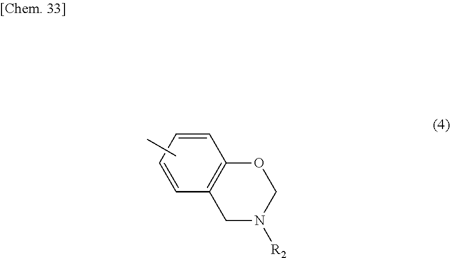

In Formula (4), R₂ represents an allyl group.

A resin composition according to a fourth aspect of the present invention is the resin composition according to the third aspect of the present invention, in which the benzoxazine compound (B1) includes a benzoxazine compound (B4) represented by the following Formula (5).

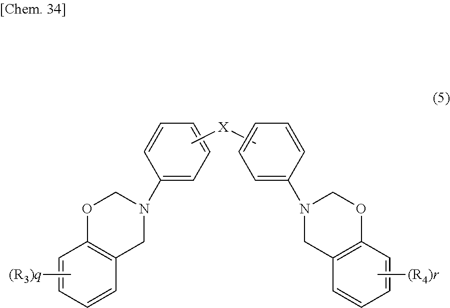

In Formula (5), R₃ and R₄ represent an allyl group, X represents an ether bond or an alkylene group, and q and r each independently represent 1 to 4.

A resin composition according to a fifth aspect of the present invention is the resin composition according to any one of the first to fourth aspects of the present invention, in which the styrenic polymer (C) includes at least one selected from the group consisting of a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a styrene butadiene block copolymer, a styrene isobutylene styrene block copolymer, a styrene (butadiene/butylene) styrene block copolymer, and hydrogenated products in which these are at least partly hydrogenated.

A resin composition according to a sixth aspect of the present invention is the resin composition according to any one of the first to fourth aspects of the present invention, in which the styrenic polymer (C) is at least partly hydrogenated.

A resin composition according to a seventh aspect of the present invention is the resin composition according to any one of the first to sixth aspects of the present invention, further containing an organic component other than the maleimide compound (A), the benzoxazine compound (B), and the styrenic polymer (C), in which the organic component includes at least one selected from the group consisting of a maleimide compound (D) different from the maleimide compound (A), a benzoxazine compound (E) different from the benzoxazine compound (B), an epoxy compound, a methacrylate compound, an acrylate compound, a vinyl compound, a cyanate ester compound, an active ester compound, and an allyl compound.

A resin composition according to an eighth aspect of the present invention is the resin composition according to any one of the first to seventh aspects of the present invention, in which a content of the maleimide compound (A) is 30 to 80 parts by mass with respect to 100 parts by mass of a sum of the maleimide compound (A) and the benzoxazine compound (B).

A resin composition according to a ninth aspect of the present invention is the resin composition according to any one of the first to eighth aspects of the present invention, in which a content of the maleimide compound (A) is 20 to 60 parts by mass with respect to 100 parts by mass of a sum of the maleimide compound (A), the benzoxazine compound (B), and the styrenic polymer (C).

A resin composition according to a tenth aspect of the present invention is the resin composition according to any one of the first to ninth aspects of the present invention, in which a content of the styrenic polymer (C) is 15 to 40 parts by mass with respect to 100 parts by mass of a sum of the maleimide compound (A), the benzoxazine compound (B), and the styrenic polymer (C).

A resin composition according to an eleventh aspect of the present invention is the resin composition according to any one of the first to tenth aspects of the present invention, further containing an inorganic filler.

A resin composition according to a twelfth aspect of the present invention is the resin composition according to the eleventh aspect of the present invention, in which a content of the inorganic filler is 50 to 250 parts by mass with respect to 100 parts by mass of a sum of the maleimide compound (A), the benzoxazine compound (B), and the styrenic polymer (C).

A prepreg according to a thirteenth aspect of the present invention is a prepreg including: the resin composition according to any one of the first to twelfth aspects of the present invention or a semi-cured product of the resin composition; and a fibrous base material.

A film with resin according to a fourteenth aspect of the present invention is a film with resin including: a resin layer containing the resin composition according to any one of the first to twelfth aspects of the present invention or a semi-cured product of the resin composition; and a support film.

A metal foil with resin according to a fifteenth aspect of the present invention is a metal foil with resin including: a resin layer containing the resin composition according to any one of the first to twelfth aspects of the present invention or a semi-cured product of the resin composition; and a metal foil.

A metal-clad laminate according to a sixteenth aspect of the present invention is a metal-clad laminate including: an insulating layer containing a cured product of the resin composition according to any one of the first to twelfth aspects of the present invention; and a metal foil.

A metal-clad laminate according to a seventeenth aspect of the present invention is a metal-clad laminate including: an insulating layer containing a cured product of the prepreg according to the thirteenth aspect of the present invention; and a metal foil.

A wiring board according to an eighteenth aspect of the present invention is a wiring board including: an insulating layer containing a cured product of the resin composition according to any one of the first to twelfth aspects of the present invention; and a wiring.

A wiring board according to a nineteenth aspect of the present invention is a wiring board including: an insulating layer containing a cured product of the prepreg according to the thirteenth aspect of the present invention; and a wiring.

According to the present invention, it is possible to provide a resin composition, which affords a cured product having a low coefficient of thermal expansion and high plating adhesion. Furthermore, according to the present invention, it is possible to provide a prepreg, a film with resin, a metal foil with resin, a metal-clad laminate, and a wiring board, which are obtained using the resin composition.

Hereinafter, the present invention will be described more specifically with reference to examples, but the scope of the present invention is not limited thereto.

### EXAMPLES

### Examples 1 to 4 and Comparative Examples 1 and 2

The respective components to be used at the time of preparing a resin composition in the present Examples will be described.

### (Maleimide Compound (A))

Maleimide compound-1: A maleimide compound synthesized as follows (maleimide compound represented by Formula (7)).

First, into a 1-L, flask equipped with a thermometer, a condenser, a Dean-Stark tube, and a stirrer, 48.5 g (0.4 mol) of 2,6-dimethylaniline, 272.0 g (1.4 mol) of α,α′-dihydroxy-1,3-diisopropylbenzene, 280 g of xylene, and 70 g of activated clay were introduced and heated to 120° C. while being stirred. Further, the temperature was raised to 210° C. while removing the distilled water through the Dean-Stark tube. By doing so, the reaction was conducted for 6 hours. After that, the reaction mixture was cooled to 140° C., 145.4 g (1.2 mol) of 2,6-dimethylaniline was introduced, and then the temperature was raised to 220° C. By doing so, the reaction was conducted for 3 hours. After the reaction, the reaction mixture was air-cooled to 100° C., and diluted with 300 g of toluene, and activated clay was removed by filtration, and low molecular weight substances such as the solvent and unreacted substances were distilled off under reduced pressure, thereby obtaining 345.2 g of a solid. The obtained solid was an amine compound (amine equivalent: 348, softening point: 71° C.) represented by the following Formula (29).

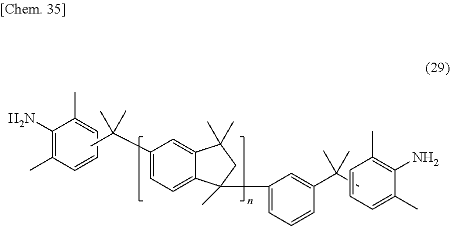

In Formula (29), n represents 0.95 to 10.

Next, 131.8 g (1.3 mol) of maleic anhydride and 700 g of toluene were introduced into a 2-L flask equipped with a thermometer, a condenser, a Dean-Stark tube, and a stirrer, and stirred at room temperature. After that, a mixed solution of 345.2 g of the amine compound represented by Formula (29) and 175 g of DMF was added dropwise over 1 hour. After completion of the dropwise addition, the mixture was further stirred at room temperature for 2 hours to conduct the reaction. After that, 37.1 g of p-toluenesulfonic acid monohydrate was added, the reaction solution was heated, and the azeotropic water and toluene were cooled and separated under reflux, and then only toluene was returned to the system, thereby conducting the dehydration reaction for 8 hours. After air-cooling to room temperature, the reaction mixture was concentrated under reduced pressure, the brown solution was dissolved in 600 g of ethyl acetate and washed with 150 g of deionized water three times and 150 g of 2% aqueous sodium bicarbonate solution three times, sodium sulfate was added for drying, then concentration was performed under reduced pressure, and the obtained reaction product was vacuum-dried at 80° C. for 4 hours, thereby obtaining 407.6 g of a solid. The obtained solid was analyzed by FD-MS spectrum, GPC and the like, and was found to be a maleimide compound represented by Formula (7) (a maleimide compound in which the amine of the amine compound represented by Formula (29) was modified with a maleimide, benzene ring equivalent: 153 g/mol, maleimide equivalent: 428 g/mol).

### (Benzoxazine Compound (B))

Benzoxazine compound: Benzoxazine compound having, in the molecule, an allyl group (benzoxazine compound represented by Formula (5), where R₃ and R₄ are each an allyl group, X is a methylene group, and q and r are 1; ALPd manufactured by SHIKOKU CHEMICALS CORPORATION)

### (Styrenic Polymer (C))

Styrenic polymer: Hydrogenated styrene (ethylene/butylene) styrene block copolymer (Tuftec H1041 manufactured by Asahi Kasei Corporation, weight average molecular weight Mw: 80000, solid at 25° C.)

### (Maleimide (D))

Maleimide compound-2: Maleimide compound not having indane structure in molecule (3,3′-dimethyl-5,5′-diethyl-4,4′-diphenylmethanebismaleimide, BM1-5100 manufactured by Daiwa Kasei Industry Co., Ltd.)

Maleimide compound-3: Maleimide compound not having indane structure in molecule (phenylmethanemaleimide, BM1-2300 manufactured by Daiwa Kasei Industry Co., Ltd.)

### (Reaction Initiator)

PBP: α,α′-Di(t-butylperoxy)diisopropylbenzene (Perbutyl P (PBP) manufactured by NOF CORPORATION)

### (Inorganic Filler)

Silica: Silica particles subjected to surface treatment with silane coupling agent having phenylamino group in molecule (SC2500-SXJ manufactured by Admatechs Company Limited)

Zinc molybdate: Z4SX-A1 manufactured by Admatechs Company Limited

### [Preparation Method]

First, the respective components other than the inorganic filler were added to and mixed in toluene at the compositions (parts by mass) shown in Table 1 so that the solid concentration was 35% by mass. The mixture was stirred for 60 minutes. Thereafter, the inorganic filler was added to the obtained liquid, and dispersed using a bead mill. By doing so, a varnish-like resin composition (varnish) was obtained.

Next, a glass cloth (#2118 type, T glass manufactured by Nitto Boseki Co., Ltd.) was impregnated with the obtained varnish, and then heated and dried at 130° C. for about 3 minutes to obtain a prepreg. At that time, the thickness of the prepreg after curing was adjusted to be about 104 μm (the content of organic components in the resin composition was about 44% by mass).

(Evaluation Substrate) Then, twelve sheets of each of the obtained prepregs were stacked, a copper foil having a thickness of 12 μm (3EC-VLP manufactured by Mitsui Mining & Smelting Co., Ltd.) was disposed on both sides thereof to obtain a body to be pressed, and the body to be pressed was heated and pressed at a temperature of 220° C. and a pressure of 3 MPa for 2 hours, thereby obtaining a copper foil-clad laminate (metal-clad laminate) having a thickness of about 1.25 mm and having copper foil pasted to both surfaces. This obtained copper foil-clad laminate was designated as an evaluation substrate.

The evaluation substrates fabricated as described above were evaluated by the methods described below.

### [Dielectric Properties (Relative Dielectric Constant Dk and Dielectric Loss Tangent Df)]

The copper foil was removed from the evaluation substrate by etching. The substrate thus obtained was used as a test piece, and the relative dielectric constant and dielectric loss tangent at 10 GHz were measured by the cavity perturbation method. Specifically, the relative dielectric constant (Dk) and dielectric loss tangent (Df) of the test piece at 10 GHz were measured using a network analyzer (N5230A manufactured by Agilent Technologies, Inc.). When the dielectric loss tangent acquired by the measurement was less than 0.0070, it was determined as “acceptable”.

### [Thermal Expansion Coefficient]

Using an unclad substrate obtained by removing the copper foil from the evaluation substrate by etching as a test piece, the thermal expansion coefficient (CTE: ppm/° C.) in the Y-axis direction was measured by TMA (thermo-mechanical analysis) in conformity with IPC TM-650. For the measurement, a TMA instrument (TMA6000 manufactured by SII NanoTechnology Inc.) was used, and the measurement was performed in a range of 50° C. to 260° C. When the thermal expansion coefficient acquired by the measurement was less than 5.5 ppm/° C., it was determined as “acceptable”.

### [Glass Transition Temperature (Tg)]

Using an unclad substrate obtained by removing the copper foil from the evaluation substrate by etching as a test piece, the Tg of the cured product of the resin composition was measured using a viscoelastic spectrometer “DMS6100” manufactured by Seiko Instruments Inc. At this time, dynamic viscoelasticity measurement (DMA) was performed with a tensile module at a frequency of 10 Hz, and the temperature at which tan δ was maximized when the temperature was raised from room temperature to 340° C. at a rate of temperature rise of 5° C./min was taken as Tg (° C.). When the glass transition temperature acquired by the measurement was more than 220° C., it was determined as “acceptable”. When the glass transition temperature Tg is higher than 310° C., it is shown as “>310” in Table 1.

### [Desmear Etching Rate]

First, the copper foil on the surface of the evaluation substrate (copper foil-clad laminate) was removed by etching. As a desmear process, the substrate from which the copper foil was removed was immersed in a swelling liquid (Swelling Dip Securiganth P manufactured by Atotech) at 60° C. for 5 minutes, then immersed in an aqueous potassium permanganate solution (Concentrate Compact CP manufactured by Atotech) at 80° C. for 10 minutes, and then subjected to neutralization. Such a desmear process was performed twice, the weight of the substrate was measured before performing the desmear process and after performing the desmear process twice, and the amount of weight decrease (weight of substrate before desmear process−weight of substrate after performing desmear process twice) due to the desmear process was calculated, and the amount of weight decrease per 1 mm² (mg/mm²) was calculated from the amount of weight decrease. Based on the amount of weight decrease per 1 mm², evaluation was performed as follows.

When the amount of weight decrease per 1 mm² was 5 mg/mm² or more and 25 mg/mm² or less, it was determined as “acceptable”. When the amount of weight decrease (desmear etching rate) is within the above range, it is found that the desmear properties are excellent.

### [Plating Adhesion]

First, the copper foil on the surface of the evaluation substrate (copper foil-clad laminate) was removed by etching. Thereafter, the same treatment as the desmear process described in the desmear etching rate evaluation was performed (the desmear process was performed twice). Thereafter, electroless copper plating and electrolytic copper plating were performed to make the thickness of copper 30 μm. This evaluation substrate was annealed at 200° C. for 20 minutes, then the copper was peeled off from the evaluation substrate, and the peel strength at that time was measured in conformity with JIS C 6481 (1996). Specifically, a pattern having a width of 10 mm and a length of 80 mm was formed on the evaluation substrate, the copper foil was peeled off at a speed of 50 mm/min using a tensile tester, and the peel strength (N/mm) at that time was measured. The peel strength is plating peel strength (plating adhesion). It was found that adhesion to plating was higher as the peel strength was higher, and when the plating peel strength obtained by measurement was more than 0.4 N/mm, it was determined as “acceptable”.

### [Copper Foil Peel Strength]

The metal foil (copper foil) was peeled off from the evaluation substrate (metal-clad laminate), and the peel strength at that time was measured in conformity with JIS C 6481 (1996). Specifically, a pattern having a width of 10 mm and a length of 100 mm was formed on the evaluation substrate, the copper foil was peeled off at a speed of 50 mm/min using a tensile tester, and the peel strength (N/mm) at that time was measured. The peel strength is copper foil peel strength. It was found that adhesion to the metal foil (copper foil) was higher as the peel strength was higher, and when the copper foil peel strength obtained by measurement was more than 0.5 N/mm, it was determined as “acceptable”.

### [Interlayer Peel Strength]

The uppermost insulating layer (prepreg) was peeled off from the evaluation substrate (metal-clad laminate) (that is, the uppermost insulating layer was peeled off from the underlying insulating layer) at a speed of 50 mm/min by a tensile tester, and the peel strength (N/mm) at that time was measured. This peel strength is interlayer peel strength. It was found that interlayer adhesion was higher as the peel strength was higher, and when the interlayer peel strength obtained by measurement was more than 0.5 N/mm, it was determined as “acceptable”.

The results of each evaluation are shown in Table 1.

TABLE 1

| | | | Example | | | | Comparative Example | |
|---|---|---|---|---|---|---|---|---|
| | | | 1 | 2 | 3 | 4 | 1 | 2 |
| Composition | (A) | Maleimide compound-1 | 49 | 20 | 28 | 55 | 70 | — |
| (parts by | (B) | Benzoxazine compound | 21 | 30 | 21 | 25 | 30 | 21 |
| mass) | (C) | Styrenic polymer | 30 | 30 | 30 | 20 | — | 30 |
| | (D) | Maleimide compound-2 | — | 15 | 21 | — | — | — |
| | | Maleimide compound-3 | — | — | — | — | — | 49 |

| | Reaction initiator | PBP | 1 | 1 | 1 | 1 | 1 | 1 |
|---|---|---|---|---|---|---|---|---|
| | Inorganic filler | Silica | 119 | 119 | 119 | 119 | 119 | 119 |
| | | Zinc molybdate | 12 | 12 | 12 | — | — | — |
| A/(A + B) × 100 | | | 70.0 | 40.0 | 57.1 | 68.8 | 70.0 | — |
| A/(A + B + C) × 100 | | | 49.0 | 25.0 | 35.4 | 55.0 | — | — |
| B/(A + B + C) × 100 | | | 21.0 | 37.5 | 26.6 | 25.0 | — | — |
| C/(A + B + C) × 100 | | | 30.0 | 37.5 | 38.0 | 20.0 | — | — |
| Inorganic filler/(A + B + C) × 100 | | | 131.0 | 163.8 | 165.8 | 119.0 | — | — |
| Evaluation | Dielectric | Relative dielectric | 3.87 | 3.91 | 3.86 | 3.83 | 3.89 | 3.87 |
| | properties | constant Dk | | | | | | |

| | | | | | | |
|---|---|---|---|---|---|---|
| Dielectric loss tangent Df | 0.0065 | 0.0069 | 0.0065 | 0.0060 | 0.0070 | 0.0062 |

| | | | | | | |
|---|---|---|---|---|---|---|
| Thermal expansion coefficient (ppm/° C.) | 4.3 | 4.8 | 5.2 | 4.9 | 6.8 | 5.7 |
| Glass transition temperature Tg (° C.) | 230 | 258 | 299 | 232 | 182 | >310 |
| Desmear etching rate (mg/mm²) | 11 | 18 | 21 | 13 | 19 | 35 |
| Plating peel strength (N/mm) | 0.62 | 0.55 | 0.48 | 0.56 | 0.71 | 0.26 |
| Copper foil peel strength (N/mm) | 0.52 | 0.52 | 0.59 | 0.57 | 0.66 | 0.58 |
| Interlayer peel strength (N/mm) | 0.78 | 0.81 | 0.99 | 0.60 | 0.45 | 0.84 |

As can be seen from Table 1, when the resin compositions containing the maleimide compound (A) having an indane structure represented by Formula (1) in the molecule, the benzoxazine compound (B) having an allyl group in the molecule, and the styrenic polymer (C) that is solid at 25° C. (Examples 1 to 4) were used, the coefficient of thermal expansion was low and the plating adhesion was high compared with those of the other cases (Comparative Example 1 and Comparative Example 2). Specifically, when the resin compositions according to Examples 1 to 4 were used, the coefficient of thermal expansion was low compared with that of the case of not containing the styrenic polymer (C) (Comparative Example 1). Also, when the resin compositions according to Examples 1 to 4 were used, not only the coefficient of thermal expansion was low but also the plating adhesion was high compared with those of the case of containing a maleimide compound other than the maleimide compound (A) having an indane structure represented by Formula (1) in the molecule (Comparative Example 2). In addition, it was found that when the resin compositions according to Examples 1 to 4 were used, cured products having not only a low coefficient of thermal expansion and high plating adhesion but also a low dielectric loss tangent, a high glass transition temperature, and excellent adhesion to a metal foil, interlayer adhesion, and desmear properties were obtained.

This application is based on Japanese patent application No. 2023-056557 filed on Mar. 30, 2023, the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

According to the present invention, there is provided a resin composition, which affords a cured product having a low coefficient of thermal expansion and high plating adhesion. In addition, the present invention provides a prepreg, a film with resin, a metal foil with resin, a metal-clad laminate, and a wiring board which are obtained using the resin composition.

1. A resin composition comprising:
a maleimide compound (A) having an indane structure represented by the following Formula (1) in a molecule;
a benzoxazine compound (B) having an allyl group in a molecule; and
a styrenic polymer (C) that is solid at 25° C.: 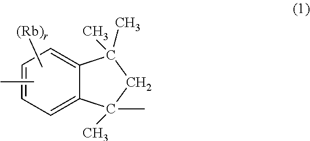
wherein in Formula (1), Rb's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group, and r represents 0 to 3.

2. The resin composition according to claim 1, wherein
the maleimide compound (A) includes a maleimide compound (A1) represented by the following Formula (2): 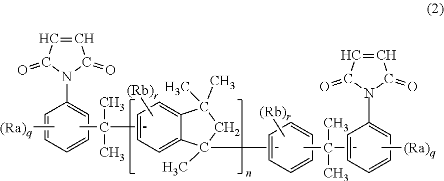
wherein in Formula (2), Ra's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group, Rb's each independently represent an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxyl group, or a mercapto group, q represents 0 to 4, r represents 0 to 3, and n represents 0.95 to 10.

3. The resin composition according to claim 1, wherein
the benzoxazine compound (B) includes at least one selected from the group consisting of a benzoxazine compound (B1) having a benzoxazine group represented by the following Formula (3) in a molecule, a benzoxazine compound (B2) having a benzoxazine group represented by the following Formula (4) in a molecule, or a benzoxazine compound (B3) having a benzoxazine group represented by the following Formula (3) and a benzoxazine group represented by the following Formula (4) in a molecule: 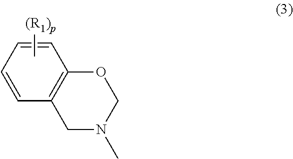
wherein in Formula (3), R₁ represents an allyl group, and p represents 1 to 4, and 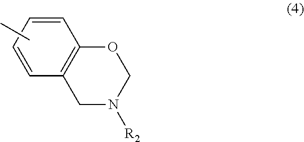
wherein in Formula (4), R₂ represents an allyl group.

4. The resin composition according to claim 3, wherein
the benzoxazine compound (B1) includes a benzoxazine compound (B4) represented by the following Formula (5): 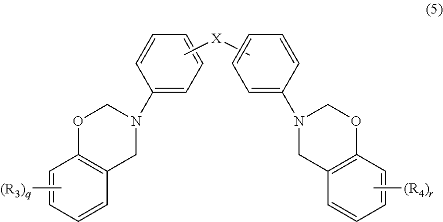
wherein in Formula (5), R₃ and R₄ represent an allyl group, X represents an ether bond or an alkylene group, and q and r each independently represent 1 to 4.

5. The resin composition according to claim 1, wherein the styrenic polymer (C) includes at least one selected from the group consisting of a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a styrene butadiene block copolymer, a styrene isobutylene styrene block copolymer, a styrene (butadiene/butylene) styrene block copolymer, and hydrogenated products in which these are at least partly hydrogenated.

6. The resin composition according to claim 1, wherein the styrenic polymer (C) is at least partly hydrogenated.

7. The resin composition according to claim 1, further comprising an organic component other than the maleimide compound (A), the benzoxazine compound (B), and the styrenic polymer (C),
wherein the organic component includes at least one selected from the group consisting of a maleimide compound (D) different from the maleimide compound (A), a benzoxazine compound (E) different from the benzoxazine compound (B), an epoxy compound, a methacrylate compound, an acrylate compound, a vinyl compound, a cyanate ester compound, an active ester compound, and an allyl compound.

8. The resin composition according to claim 1, wherein a content of the maleimide compound (A) is 30 to 80 parts by mass with respect to 100 parts by mass of a sum of the maleimide compound (A) and the benzoxazine compound (B).

9. The resin composition according to claim 1, wherein a content of the maleimide compound (A) is 20 to 60 parts by mass with respect to 100 parts by mass of a sum of the maleimide compound (A), the benzoxazine compound (B), and the styrenic polymer (C).

10. The resin composition according to claim 1, wherein a content of the styrenic polymer (C) is 15 to 40 parts by mass with respect to 100 parts by mass of a sum of the maleimide compound (A), the benzoxazine compound (B), and the styrenic polymer (C).

11. The resin composition according to claim 1, further comprising an inorganic filler.

12. The resin composition according to claim 11, wherein a content of the inorganic filler is 50 to 250 parts by mass with respect to 100 parts by mass of a sum of the maleimide compound (A), the benzoxazine compound (B), and the styrenic polymer (C).

13. A prepreg comprising:
the resin composition according to claim 1 or a semi-cured product of the resin composition; and
a fibrous base material.

14. A film with resin comprising:
a resin layer containing the resin composition according to claim 1 or a semi-cured product of the resin composition; and
a support film.

15. A metal foil with resin comprising:
a resin layer containing the resin composition according to claim 1 or a semi-cured product of the resin composition; and
a metal foil.

16. A metal-clad laminate comprising:
an insulating layer containing a cured product of the resin composition according to claim 1; and
a metal foil.

17. A metal-clad laminate comprising:
an insulating layer containing a cured product of the prepreg according to claim 13; and
a metal foil.

18. A wiring board comprising:
an insulating layer containing a cured product of the resin composition according to claim 1; and
a wiring.

19. A wiring board comprising:
an insulating layer containing a cured product of the prepreg according to claim 13; and
a wiring.
